(19) United States
(12) Patent Application Publication
(10) Pub. No.: US 2008/0308905 A1
(43) Pub. Date: Dec. 18, 2008

(54) SEMI-CONDUCTOR DEVICE, AND METHOD OF MAKING THE SAME

(75) Inventor: Ji Hwan PARK, Chungju-si (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 12/139,347

(22) Filed: Jun. 13, 2008

(30) Foreign Application Priority Data
Jun. 14, 2007 (KR) 10-2007-0058477

(51) Int. Cl. H01L 21/265; H01L 29/36

(52) U.S. Cl. 257/607; 438/525; 257/E21.334; 257/E29.109

(57) ABSTRACT

A semiconductor device and a method for manufacturing the device are disclosed. The device, and the method for making the device, includes the steps of forming a gate oxide film on a semiconductor substrate; forming a gate poly silicon layer on the gate oxide film; and implanting deuterium ions over the semiconductor substrate including the gate poly silicon layer.

### CROSS-REFERENCE TO A RELATED APPLICATION

This application claims the benefit of Korean Patent Application No. 10-2007-0058477, filed on 14 Jun. 2007, which is hereby incorporated by reference as if fully set forth herein.

### BACKGROUND

1. Field of the Invention

Embodiments of the present invention relate to methods of manufacturing a semiconductor device, and in particular to a semiconductor device and a manufacturing method thereof, suitable for improving the reliability of a gate oxide film.

2. Discussion of the Related Art

Generally, with the high integration of a semiconductor device, various technologies for manufacturing a thin film semiconductor device having characteristics of high speed operation and low power consumption have been introduced.

One example of a conventional process for manufacturing a thin film semiconductor device uses a low pressure chemical vapor deposition (LP-CVD) method for depositing amorphous silicon thin film at low pressure and at a predetermined temperature on the semiconductor substrate.

Typically, this LP-CVD methodology uses a furnace. Further, in this particular example the device is formed by depositing polysilicon by performing the LP-CVD using SiH₄ gas just after forming a gate oxide film using the furnace.

One drawback of this particular approach is that the gate oxide film formed contains a considerable amount of hydrogen. Also, in any subsequent processes using hydrogen, the gate oxide film may include hydrogen. The presence of hydrogen within the gate oxide film acts as a factor deteriorating the reliability of the gate oxide film by the electron trap. This problem is made worse in highly integrated semiconductor devices because the device size is smaller and the electrical characteristics are affected due to hydrogen remaining within the layer.

### SUMMARY OF EXAMPLE EMBODIMENTS

In general, example embodiments of the present invention relate to semiconductor devices and manufacturing methods thereof, that are suitable for improving the reliability of a gate oxide film. In particular, proposed embodiments seek to minimize the deterioration of the electrical characteristics of a gate oxide film due to the effect of hydrogen remaining within the gate oxide film.

In one example embodiment, a method for manufacturing a semiconductor device includes the steps of forming a gate oxide film on a semiconductor substrate; forming a gate poly silicon layer on the gate oxide film; and implanting deuterium ions over the semiconductor substrate including the gate poly silicon layer.

In one embodiment, after forming the gate oxide film, the silicon nitride film is uniformly deposited at several nm by an atomic layer deposition.

In example embodiments, the deuterium ions are implanted at predefined implantation amount and at a predetermined ion implantation angle.

In disclosed embodiments, after the implantation of the deuterium ions, the gate poly silicon layer is formed on the silicon nitride film.

In another example embodiment, a method for forming a semiconductor device includes the steps of forming a gate oxide film on a semiconductor substrate; implanting deuterium ions over the semiconductor substrate including the gate oxide film; forming a gate poly silicon layer on the gate oxide film implanted with the deuterium ion.

In one embodiment, the deuterium ion implanting layer is diffused into the gate oxide film and the silicon nitride film. Also, the deuterium ion implanting layer is diffused into the gate oxide film, and the silicon nitride film and the gate poly silicon layer.

In yet another example embodiment, a semiconductor device is provided, which includes a gate oxide film formed on a semiconductor substrate; a gate poly silicon layer formed on the gate oxide film; and a deuterium ion implanting layer formed by implanting deuterium ions over the semiconductor substrate including the gate oxide film.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWING

FIG. 1 shows a formation structure of a semiconductor device according to one example embodiment.

FIG. 2 shows a process example implanting deuterium ions into a semiconductor device according an example embodiment.

### DETAILED DESCRIPTION OF EXAMPLE EMBODIMENTS

In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

In general, embodiments of the present invention are directed to improving the reliability of the oxide film configuring the semiconductor device. In disclosed embodiments, deuterium D2 (heavy hydrogen) ions are implanted into the oxide film. The deuterium has larger mass relative to hydrogen and has high coupling possibility with silicon relative to hydrogen. In this way, interface characteristics between the gate oxide film and the gate electrode are improved through the deuterium ion implantation.

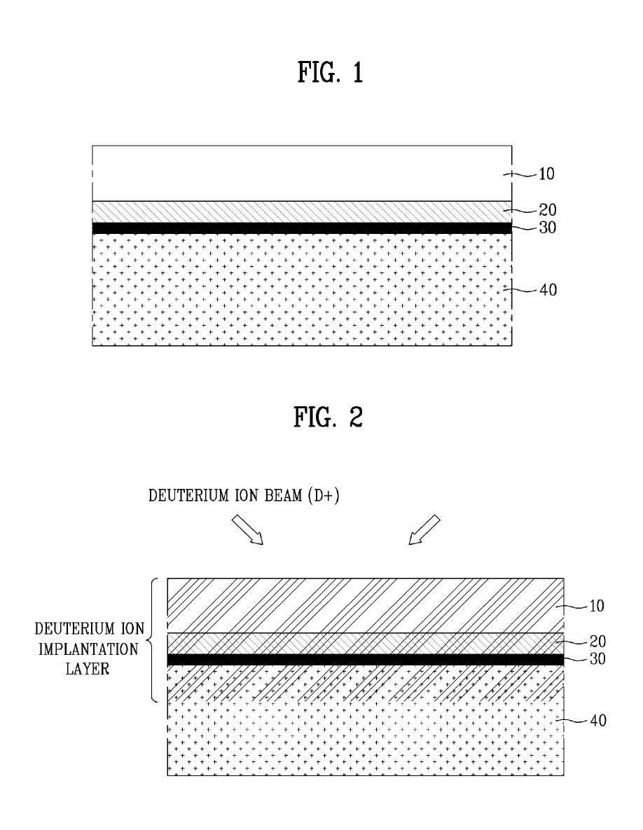

FIG. 1 shows a formation structure of a semiconductor device according to an example embodiment. FIG. 2 illustrates one example of a process for implanting deuterium ions into a semiconductor device.

Referring to FIGS. 1 and 2, a semiconductor device according to an example embodiment has a stacked structure of a semiconductor substrate 40, a gate oxide film 30, a silicon nitride film 20, and a gate poly silicon layer 10 from the lower thereof.

In the illustrated example, the gate oxide film 30, the silicon nitride film 20, and the gate polysilicon layer 10 are sequentially deposited on the semiconductor substrate 40 in order.

For example, the gate oxide film 30 is formed by depositing oxide on an upper of an active region of the semiconductor substrate 40. Next, the silicon nitride is deposited on the gate oxide film 30 to form the silicon nitride film 20. At this time, to provide the formation of the silicon nitride film 20, the deposition is performed, for example, by an atomic layer deposition (ALD). In particular, the silicon nitride is uniformly deposited at several nm by the ALD. The damage of the gate oxide film 30 can be prevented in implanting ions by depositing the silicon nitride of several nm on the upper of the gate oxide film 30 by the ALD. Also, in order to prevent the diffusion against boron penetration in a p-MOS, the silicon nitride is uniformly deposited at several nm by the ALD.

Polysilicon is then deposited on the silicon nitride film 20 to form the gate polysilicon layer 10.

As described above, the gate oxide film 30, the silicon nitride film 20, and the gate polysilicon layer 10 are sequentially stacked on the active region of the semiconductor device 40. In the illustrated embodiment, the deuterium ions are then implanted at a predetermined implantation amount, as is denoted in FIG. 2.

In the illustrated example, the deuterium ion implantation sets the implantation conditions to be implanted at a relatively shallow depth.

For example, the implanted amount of the deuterium ions is set to approximately 1E15 dose/cm² to 1E17 dose/cm², and preferably at 1E16 dose/cm². The ion implantation angle for implanting the deuterium ions is maintained at a higher implantation angle relative to a stacking surface. For example, in the illustrated example the implantation angle is approximately 30 to 60°.

In one example, ions can be implanted in a four step scan method. Herein, the four step scan method means implanting ions while changing the wafer direction to 90°. The ion amount implanted in all directions is ¼ relative to a total amount of ions to be implanted. Also, for example, the ion implantation condition is set so that the deuterium ions are implanted to a predetermined depth of the semiconductor substrate 40.

After the gate polysilicon layer 10 is formed as above, the deuterium ion implanting layer is formed by the deuterium ion implantation. In this way, the deuterium ion implantation layer is formed in a structure diffused into the gate oxide film 30, the silicon nitride film 20, and the gate polysilicon layer 10. As shown in FIG. 2, it can be diffused to the semiconductor substrate 40 to some extent.

After the deuterium ion implanting layer is formed, the stacked films are sequentially removed using, for example, a gate forming mask pattern (not shown) to form the gate electrode.

In another embodiment, after the gate oxide film 30 and the silicon nitride film 20 are deposited on the semiconductor substrate 40, the deuterium ions are implanted over the substrate. In this case, the gate polysilicon layer 10 is formed after the deuterium ion implantation. And, the stacked films are sequentially removed using the gate forming mask pattern to form the gate electrode.

To summarize, in example embodiments the deuterium D2 ions are implanted into the gate oxide film 30, making it possible to improve the electrical characteristic and reliability of the gate oxide film 30. Moreover, the deterioration of the electrical characteristic of the gate oxide film due to the effect of hydrogen existing in the gate oxide film can be prevented.

Although example embodiments of the present invention have been shown and described, changes might be made in these example embodiments. The scope of the invention is therefore defined in the following claims and their equivalents.

What is claimed is:

1. A method for manufacturing a semiconductor device including the steps of:
forming a gate oxide film on a semiconductor substrate;
forming a gate poly silicon layer on the gate oxide film; and
implanting deuterium ions over the semiconductor substrate including the gate poly silicon layer.

2. The method according to claim 1, further including forming a silicon nitride film on the gate oxide film,
wherein the gate poly silicon layer is formed on the silicon nitride film.

3. The method according to claim 2, wherein the silicon nitride film is substantially uniformly deposited by an atomic layer deposition (ALD).

4. The method according to claim 1, wherein the deuterium ions are implanted at an implantation amount of about 1E15 to 1E16 dose/cm².

5. The method according to claim 1, wherein an ion implantation angle for implanting the deuterium ions is maintained at about 30 to 60°.

6. The method according to claim 1, wherein the deuterium ions are implanted to the semiconductor substrate.

7. The method according to claim, 1, wherein the deuterium ions are implanted in four step scan method.

8. A method for making a semiconductor device, the method including the steps of:
forming a gate oxide film on a semiconductor substrate;
implanting deuterium ions over the semiconductor substrate including the gate oxide film; and
forming a gate poly silicon layer on the gate oxide film implanted with the deuterium ion.

9. The method according to claim 8, further including forming a silicon nitride film on the gate oxide film,
wherein the deuterium ions being implanted over the semiconductor substrate including the silicon nitride film and the gate poly silicon layer is formed on the silicon nitride film implanted with the deuterium ions.

10. A semiconductor device including:
a gate oxide film disposed on a semiconductor substrate;
a gate poly silicon layer disposed on the gate oxide film; and
a deuterium ion implanting layer disposed over the semiconductor substrate including the gate oxide film.

11. The semiconductor device according to claim 10, further including a silicon nitride film disposed on the gate oxide film,
wherein the gate poly silicon layer is disposed on the silicon nitride layer.

12. The semiconductor device according to claim 10, wherein the deuterium ion implanting layer is diffused into the gate oxide film and the silicon nitride film.

13. The semiconductor device according to claim 10, wherein the deuterium ion implanting layer is diffused into the gate oxide film, the silicon nitride film, and the gate poly silicon layer.
